(19) United States
(12) Patent Application Publication
(10) Pub. No.: US 2017/0025389 A1
(43) Pub. Date: Jan. 26, 2017

(54) Three-Dimensional Mask-Programmed Read-Only Memory With Reserved Space

(71) Applicant: Guobiao ZHANG, Corvallis, OR (US)

(72) Inventor: Guobiao ZHANG, Corvallis, OR (US)

(73) Assignee: ChengDu HaiCun IP Technology LLC, ChengDu (CN)

(21) Appl. No.: 15/284,534

(22) Filed: Oct. 3, 2016

Related U.S. Application Data
(63) Continuation-in-part of application No. 14/491,999, filed on Sep. 20, 2014.
Application No. 14/491,999 is a continuation-in-part of application No. 13/846,928, filed on Mar. 18, 2013, now Pat. No. 8,885,384.
Application No. 13/846,928 is a continuation-in-part of application No. 13/396,596, filed on Feb. 14, 2012, now abandoned.
Application No. 13/396,596 is a continuation-in-part of application No. 12/883,172, filed on Sep. 15, 2010, now abandoned.
Application No. 12/883,172 is a continuation-in-part of application No. 11/736,773, filed on Apr. 18, 2007, now abandoned.
(60) Provisional application No. 60/884,618, filed on Jan. 11, 2007.

(51) Int. Cl. H01L 25/065; H01L 27/105; G11C 5/02

(52) U.S. Cl. CPC H01L 25/0657; G11C 5/02; H01L 27/105; H01L 2225/06527; H01L 2225/06548; H01L 2225/06568; H01L 27/11206

(57) ABSTRACT

The present invention discloses a 3D-MPROM with reserved level (3D-MPROM_{RL}). Versions of the 3D-MPROM_{RL}, including an original 3D-MPROM_{RL} and at least an updated 3D-MPROM_{RL}, collectively form a 3D-MPROM_{RL} family. Within a 3D-MPROM_{RL} family, 3D-MPROM_{RL}'s of different versions are same except for at least a reserved level, which is absent in the original 3D-MPROM_{RL} but present in the updated 3D-MPROM_{RL}.

### CROSS-REFERENCE TO RELATED APPLICATIONS

This application is a continuation-in-part of U.S. patent application Ser. No. 14/491,999, “Three-Dimensional Mask-Programmed Read-Only Memory with Reserved Space”, filed Sep. 20, 2014, which is a continuation-in-part of U.S. patent application Ser. No. 13/846,928, “Mask-Programmable Memory with Reserved Space”, filed Mar. 18, 2013, which is a continuation-in-part of U.S. patent application Ser. No. 13/396,596, “Mask-Programmable Memory with Reserved Space”, filed Feb. 14, 2012, which is a continuation-in-part of U.S. patent application Ser. No. 12/883,172, “Three-Dimensional Mask-Programmable Memory with Reserved Space”, filed Sep. 15, 2010, which is a continuation-in-part of U.S. patent application Ser. No. 11/736,773, “Mask-Programmable Memory with Reserved Space”, filed Apr. 18, 2007, which is a non-provisional application of a U.S. Patent Application Ser. No. 60/884,618, “Mask-Programmable Memory with Reserved Space”, filed Jan. 11, 2007.

### BACKGROUND

1. Technical Field of the Invention

The present invention relates to the field of integrated circuits, and more particularly to three-dimensional mask-programmed read-only memory (3D-MPROM).

2. Prior Arts

Three-dimensional mask-programmed read-only memory (3D-MPROM) is a mask-ROM whose memory cells are distributed in a 3-D space. U.S. Pat. No. 5,835,396, issued to Zhang on Nov. 10, 1998, discloses a 3D-MPROM. As is illustrated in FIGS. 2A-2C of this Specification (also disclosed in FIGS. 3A-3C, 8A-8C and 9A-9C), a 3D-MPROM 40 comprises at least a first memory level 10 (FIG. 2A). The memory cells in the first memory level 10 form a first memory array 10AY. Furthermore, the 3D-MPROM 40 comprises a first peripheral circuit 10PC, which is formed on the substrate 0 (FIG. 2B). Coupled with the first memory array 10AY through a plurality of contact vias 110av (FIG. 2A), the first peripheral circuit 10PC performs read operation for the first memory array 10AY (FIG. 2C).

In a 3D-MPROM, the contents are written using at least one data-mask during manufacturing process (step 10 of FIG. 1C). FIG. 1A discloses an exemplary data-mask 2. It comprises a plurality of mask-regions 2a-2i, whose patterns represent content data 4a-4i. Hereinafter, the pattern representing content data is referred to as data-pattern. Being permanently formed, the data-patterns cannot be modified once written onto the data-mask 2.

The 3D-MPROM that stores the original contents is referred to as the original 3D-MPROM. When a new content becomes available, a newly manufactured 3D-MPROM needs to store the new content, in addition to the original contents. In the present invention, the newly manufactured 3D-MPROM is referred to as an updated 3D-MPROM. From the original 3D-MRPOM to the updated 3D-MPROM, it generally involves a hardware revision, e.g. at least one data-mask and/or at least one peripheral circuit need to be revised.

For a small content revision (i.e. the new content is small), the original data-mask 2 is replaced with a new data-mask 2x (step 12 of FIG. 1C). An example is illustrated in FIG. 1B. The new data-mask 2x includes the data-pattern of the new content 4e* in the mask-region 2e, as well as the data-patterns for the original contents 4a-4d, 4f-4i. The original and new contents 4a-4d, 4e*, 4f-4i are written to the updated 3D-MPROM using the new data-mask 2x (step 14 of FIG. 1C).

As technology advances, data-mask becomes more and more expensive. For example, a 22 nm data-mask costs ˜$260k. In addition, a data-mask contains more and more data. For example, a 22 nm data-mask could contain up to ˜155GB data. Some of these data will likely be revised at a future point of time. Replacing a whole data-mask for a small content revision is costly. To overcome this and other drawbacks, the present invention discloses a three-dimensional 3D-MPROM with reserved space (3D-MPROM_{RS}).

For a large content revision (i.e. the new content is large), at least one additional memory level, in addition to the original memory level(s) in the original 3D-MPROM, is formed in the updated 3D-MPROM. An example is illustrated in FIGS. 3A-3C. The additional second memory level 20 is formed on top of the first memory level 10 (FIG. 3A). The memory cells in the second memory levels 20 form a second memory array 20AY. Besides the first peripheral circuit 10PC, the 3D-MPROM 40* further comprises a second peripheral circuit 20PC (formed on the substrate 0*) (FIG. 3B), which performs read operation for the second memory array 20AY (FIG. 3C). Because the peripheral circuits in the original 3D-MPROM 40 does not comprise the peripheral circuit 20PC of the memory level 20, the peripheral circuits in the updated 3D-MPROM 40* need to be revised from those in the original 3D-MPROM 40.

Revision of the peripheral circuits is much more expensive than revision of the data-mask. Revision of the data-mask usually involves a small number of masks (e.g. one or two masks), but revision of the peripheral circuits generally involves a large number of masks (e.g. around twenty masks). As a result, increasing the number of the memory level(s) in a 3D-MPROM is prohibitively expensive. To overcome this and other drawbacks, the present invention discloses a three-dimensional 3D-MPROM with reserved level(s) (3D-MPROM_{RL}).

### Objects and Advantages

It is a principle object of the present invention to provide a 3D-MPROM that can economically accommodate content revision.

It is a further object of the present invention to provide a 3D-MPROM which salvages the original data-mask for content revision.

It is a further object of the present invention to provide a 3D-MPROM which salvages the original peripheral circuits for content revision.

In accordance with these and other objects of the present invention, 3D-MPROM with reserved space (3D-MPROM_{RS}) and 3D-MPROM with reserved level(s) (3D-MPROM_{RL}) are disclosed.

### SUMMARY OF THE INVENTION

The present invention discloses a 3D-MPROM with reserved space (3D-MPROM_{RS}). For a small content revision, the original data-mask can be salvaged. Hereinafter, small content revision means the amount of new content that are to be added at a future point of time is substantially less than the original contents. On the original data-mask, at least one mask-region is reserved for new content and has no data-pattern. This reserved mask-region can be used to write the data-pattern of the new content when it becomes available. Versions of the 3D-MPROM_{RS}, including an original 3D-MPROM_{RS} and at least an updated 3D-MPROM_{RS}, collectively form a 3D-MPROM_{RS} family. Within a 3D-MPROM_{RS} family, 3D-MPROM_{RS} of different versions are same except for at least a reserved portion, which stores no content in the original 3D-MPROM_{RS} but stores the new content in the updated 3D-MPROM_{RS}.

The present invention further discloses a three-dimensional 3D-MPROM with reserved memory level(s) (3D-MPROM_{RL}), which can accommodate at least one large content revision. Versions of the 3D-MPROM_{RL}, including an original 3D-MPROM_{RL} and at least an updated 3D-MPROM_{RL}, collectively form a 3D-MPROM_{RL} family. Within a 3D-MPROM_{RL} family, 3D-MPROM_{RL}'s of different versions are same except for at least a reserved level, which is absent in the original 3D-MPROM_{RL} but present in the updated 3D-MPROM_{RL}. To be more specific, the contents stored in the original 3D-MPROM_{RL} (i.e. the original contents) are also stored in the updated 3D-MPROM_{RL}. While the original 3D-MPROM_{RL} comprises fewer memory levels (i.e. without the reserved memory level) than the updated 3D-MPROM_{RL}, they comprise the same peripheral circuits.

As an example, the original 3D-MPROM_{RL} comprises M (M is a positive integer) memory levels (from the 1^{st} memory level to the M^{th} memory level), whereas the updated 3D-MPROM_{RL} comprises N (N is a positive integer, N>M) memory levels (from the 1^{st} memory level to the N^{th} memory level), where N−M memory levels (from the M+1^{th} memory level to the N^{th} memory level) are considered as reserved memory levels. Even though it comprises M memory levels, the original 3D-MPROM_{RL} still comprises the peripheral circuits for N(N>M) memory levels. Generally, the first M memory levels of the updated 3D-MPROM_{RL} store the original contents, whereas its next N−M memory levels store the new content. Preferably, the first M memory levels of the updated 3D-MPROM_{RL} are same as the M memory levels of the original 3D-MPROM_{RL}.

### BRIEF DESCRIPTION OF THE DRAWINGS

FIGS. 1A-1B illustrate original and new data-masks in prior art; FIG. 1C discloses a data-writing method to the original and new 3D-MPROMs in prior art;

FIG. 2A is a cross-sectional view of a prior-art 3D-MPROM in its original version;

FIG. 2B is a top view of its substrate; FIG. 2C is its circuit block diagram;

FIG. 3A is a cross-sectional view of a prior-art 3D-MPROM in its updated version; FIG. 3B is a top view of its substrate; FIG. 3C is its circuit block diagram;

FIGS. 4A-4B illustrate exemplary original and updated data-masks 6, 6*; FIG. 4C discloses a preferred data-writing method to the original and updated 3D-MPROM_{RS}'s;

FIGS. 5AA-5BB illustrate details of a 3D-MPROM_{RS} family. Among them, FIGS. 5AA-5AB are different views of an original 3D-MPROM_{RS} array 30; FIGS. 5BA-5BB are different views of an updated 3D-MPROM_{RS} array 30*;

FIG. 6 is a circuit block diagram of a preferred 3D-MPROM_{RS};

FIG. 7A discloses an exemplary address-mapping table of an original 3D-MPROM_{RS}; FIGS. 7B-7C disclose exemplary address-mapping tables of two updated 3D-MPROM_{RS}'s;

FIGS. 8A-9C illustrate details of a preferred 3D-MPROM_{RL} family. Among them, FIG. 8A is a cross-sectional view of a preferred original 3D-MPROM_{RL}, FIG. 8B is a top view of its substrate, FIG. 8C is its circuit block diagram; FIG. 9A is a cross-sectional view of a preferred updated 3D-MPROM_{RL}, FIG. 9B is a top view of its substrate, FIG. 9C is its circuit block diagram.

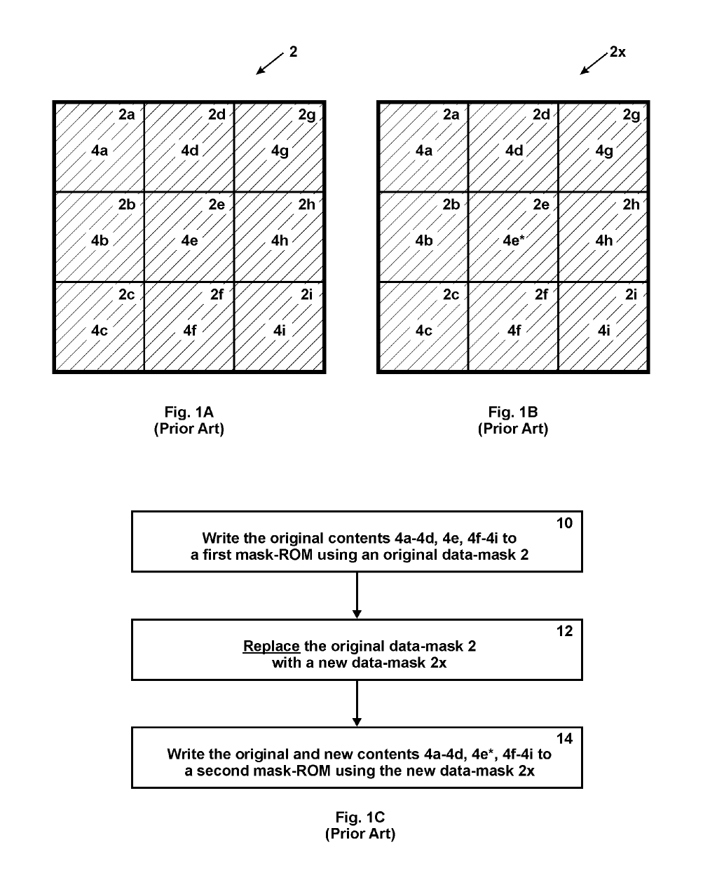

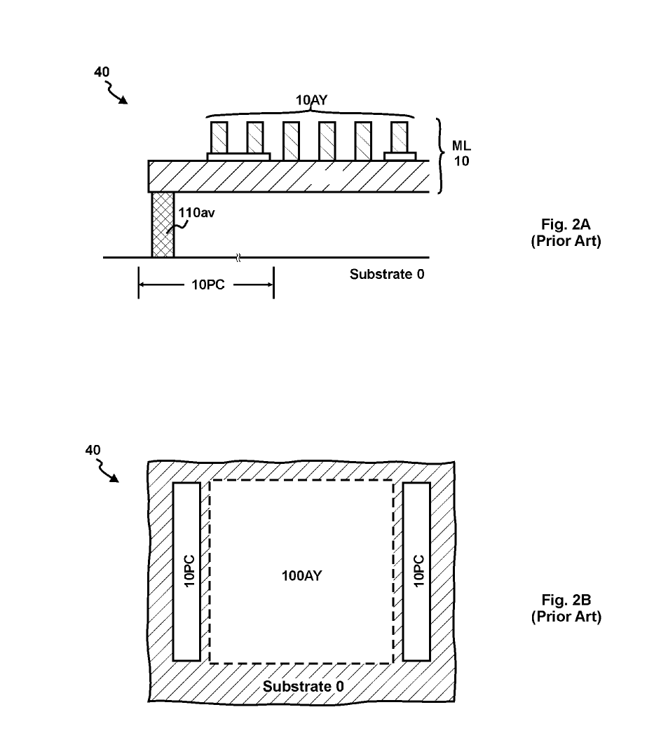

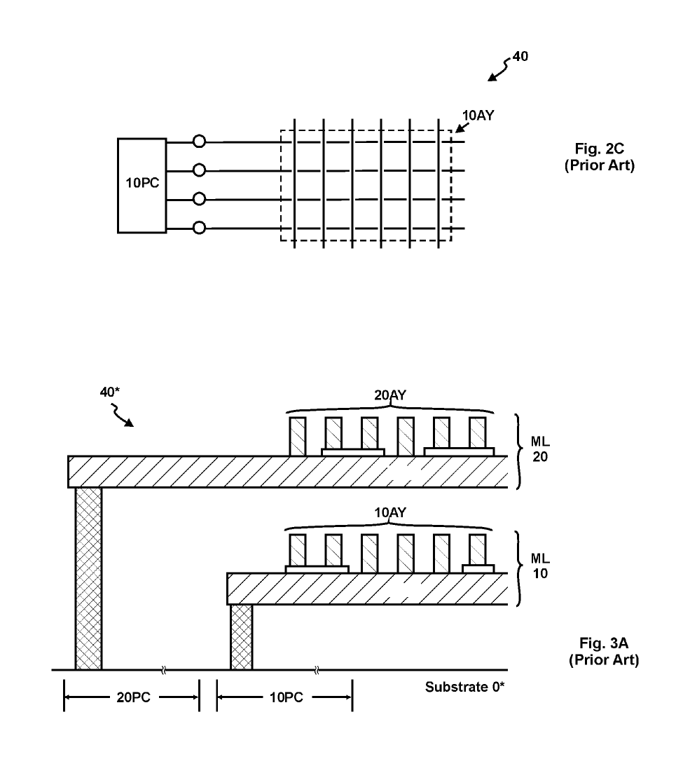

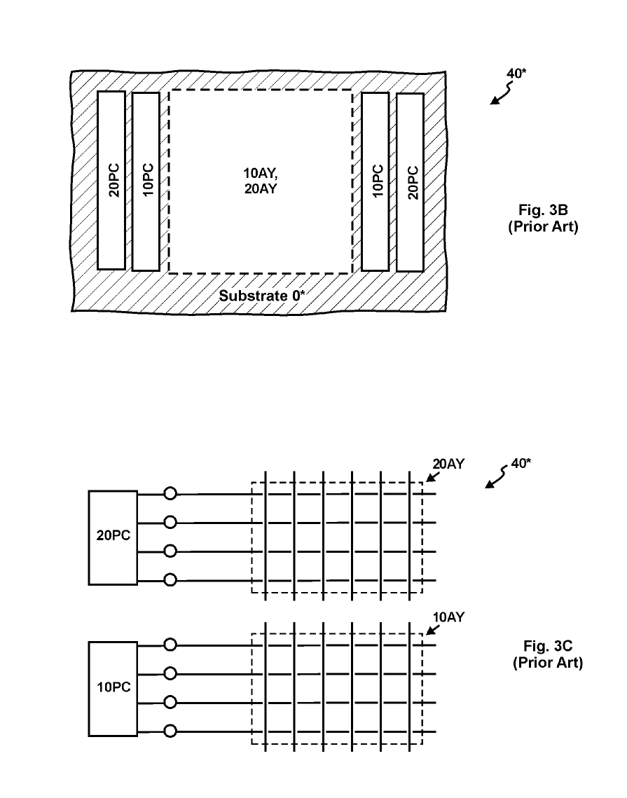

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

In this specification, the term “original” refers to the first version of the 3D-MPROM, which stores an initial collection of contents, i.e. original contents. The term “updated” refers to the second or later version of the 3D-MPROM, which stores at least a new content, in addition to the original contents. The new content could be included as an additional content, which adds to the original contents; or as an upgrade content, which replaces an outdated content in the original contents.

In this specification, “content” can be broadly interpreted as a standalone content or a component thereof. Hereinafter, “standalone content” refers to information which, by itself, provides value for an end-user in specific context. A content could be a single file or a collection of files. One example of content is a multimedia content, including a textual content, an audio content, an image content (e.g. a digital map) and/or a video content (e.g. a movie, a TV program, a video game). Another example of content is a computer program, including an operating system, a computer software for computers and/or an application software for cellular phones.

The present invention discloses a 3D-MPROM with reserved space (3D-MPROM_{RS}). For a small content revision, the original data-mask can be salvaged. Hereinafter, small content revision means the amount of new content that are to be added at a future point of time is substantially less than the original contents. On the original data-mask, at least one mask-region is reserved for new content and has no data-pattern. This reserved mask-region can be used to write the data-pattern of the new content when it becomes available. Versions of the 3D-MPROM_{RS}, including an original 3D-MPROM_{RS} and at least an updated 3D-MPROM_{RS}, collectively form a 3D-MPROM_{RS} family. Within a 3D-MPROM_{RS} family, 3D-MPROM_{RS} of different versions are same except for at least a reserved portion, which stores no content in the original 3D-MPROM_{RS} but stores the new content in the updated 3D-MPROM_{RS}.

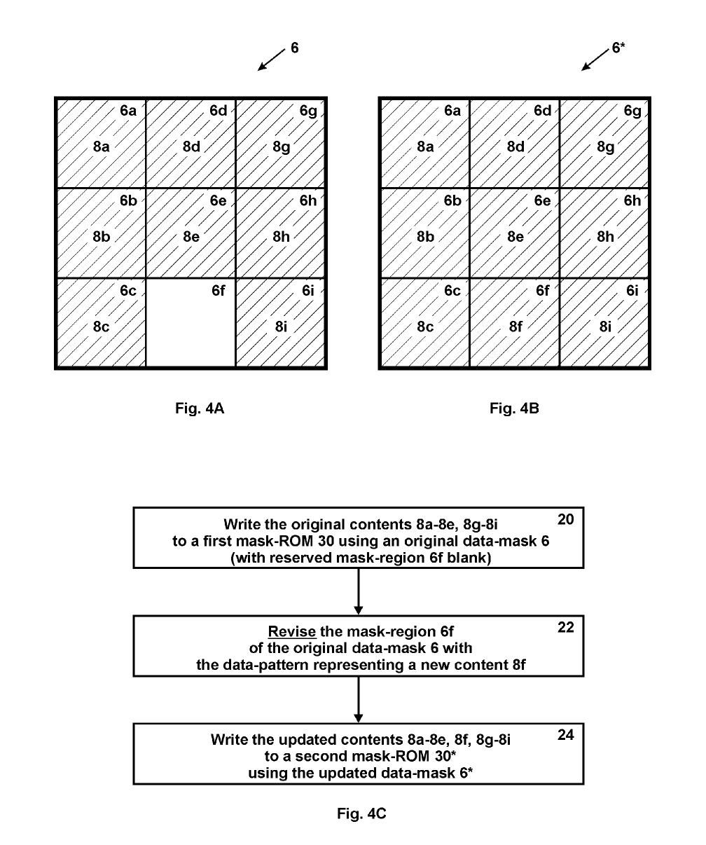

Referring now to FIGS. 4A-4C, the original and updated data-masks used for a preferred 3D-MPROM_{RS} and a preferred data-writing method are disclosed. The original data-mask 6 comprises a plurality of mask-regions 6a-6i (FIG. 4A). Most mask-regions 6a-6e, 6g-6i have data-patterns representing data for the original contents 8a-8e, 8g-8i. However, at least one mask-region 6f is reserved for at least a future new content and has no data-pattern. This mask-region 6f is blank, i.e. either all dark or all clear. The original contents 8a-8e, 8g-8i are written into a first batch of 3D-MPROM_{RS}'s (i.e. original 3D-MPROM_{RS}'s) using the original data-mask 6 (step 20 of FIG. 4C).

When a new content 8f needs to be included in an updated 3D-MPROM_{RS}, the data-pattern representing this new content 8f is written to the reserved mask-region 6f (step 22 of FIG. 4C). As a result, the updated data-mask 6* contains the data-patterns representing the original contents 8a-8e, 8g-8i plus the new content 8f (FIG. 4B). These contents 8a-8e, 8f, 8g-8i are written into a second batch of 3D-MPROM_{RS}'s (i.e. updated 3D-MPROM_{RS}'s) using the updated data-mask 6* (step 24 of FIG. 4C). In the present invention, because the first and second batches of 3D-MPROM_{RS}'s use the same data-mask 6 (with revision, not two different data-masks 2 and 2x as in prior arts), they are referred to as a 3D-MPROM_{RS} family. Because the original data-mask 6 is salvaged, little extra mask cost is incurred for a small content revision. It should be noted that, to make it economically feasible to salvage the original data-mask, the original contents should occupy a substantial portion of the original data-mask.

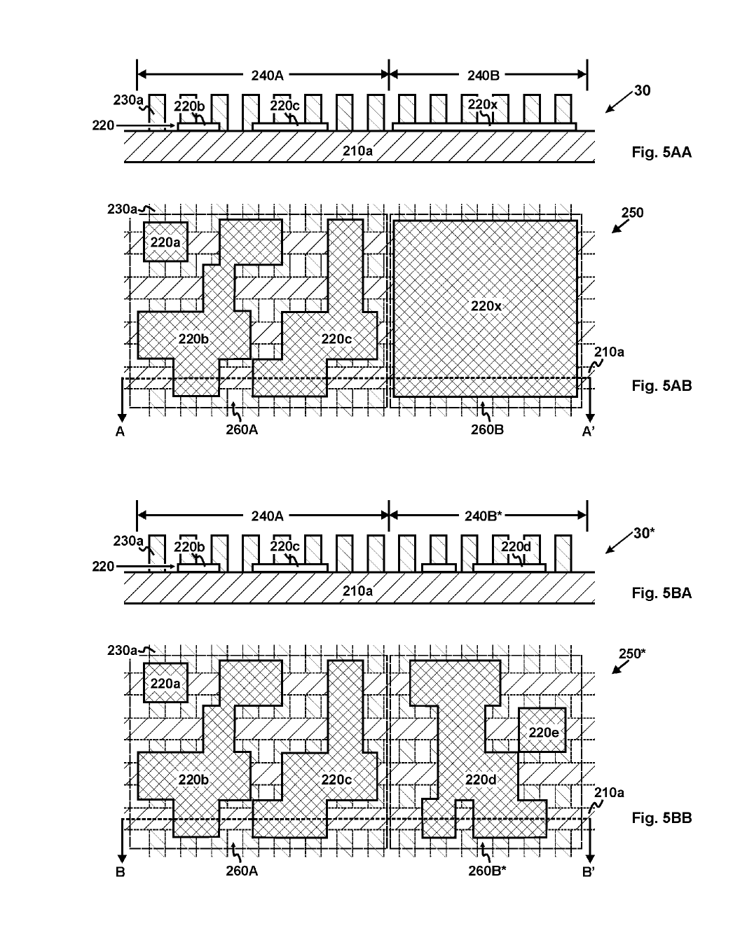

Referring now to FIGS. 5AA-5BB, a preferred 3D-MPROM_{RS} family is disclosed. It comprises an original 3D-MPROM_{RS} array 30 (FIGS. 5AA-5AB) and an updated 3D-MPROM_{RS} array 30* (FIGS. 5BA-5BB). The 3D-MPROM_{RS} array 30 (or 30*) comprises a plurality of lower address lines (210a . . . ) and upper address line (230a . . . ) and 3D-MPROM cells. Each memory cell further comprises at least a data-layer 220, whose existence or absence determines the digital state of the memory cell. Examples of the data-layer include an insulating dielectric or a resistive layer. The data-pattern of the data-layer is defined by the data-mask 6 (or 6*). For reason of simplicity, diodes, transistors and other memory components are not shown in FIGS. 5AA-5BB.

FIG. 5AA is a cross-sectional view of the original 3D-MPROM_{RS} array 30 along the cut-line AA′ of FIG. 5AB; FIG. 5AB is a top view of the data-pattern 250 of the data-layer 220 in the original 3D-MPROM_{RS} array 30 and its relative placement with respect to the address lines 210a . . . ; 230a . . . . The 3D-MPROM_{RS} array 30 comprises a first portion 240A and a second portion 240B. The first portion 240A corresponds to the region 260A of the data-layer 250, which has data-patterns 220a-220c. Accordingly, the memory cells in the first portion 240A are associated with a plurality of data blocks. They store the original content and form the original data space. On the other hand, the second portion 240B corresponds to the region 260B of the data-layer 250, which has no data-pattern, or just an all-dark pattern 220x. Accordingly, the memory cells in the second portion 240B are associated with a plurality of empty blocks. They store no content and form a reserved space. Hereinafter, a “block” is the smallest allocation unit of a memory that can be addressed by a user (or, a host). A “data block” is a block whose data has been written, while an “empty block” is a block whose data has not been written.

FIG. 5BA is the cross-sectional view of the updated 3D-MPROM_{RS} array 30* along the cut-line BB′ of FIG. 5BB; FIG. 5BB is the top view of the updated data-pattern 250* of the data-layer 220 and its relative placement with respect to the address lines 210a . . . ; 230a . . . . Here, the original data-patterns 220a-220c remain the same. However, the updated data-patterns 220d, 220e representing the new content are written into the region 260B* of the data-layer 220. Accordingly, the memory cells in the second portion 240B* stores the new content. To simplify manufacturing during content revision, it is preferred that the reserved portion 240B (240B*) is located at the topmost level of all memory levels in a 3D-MPROM.

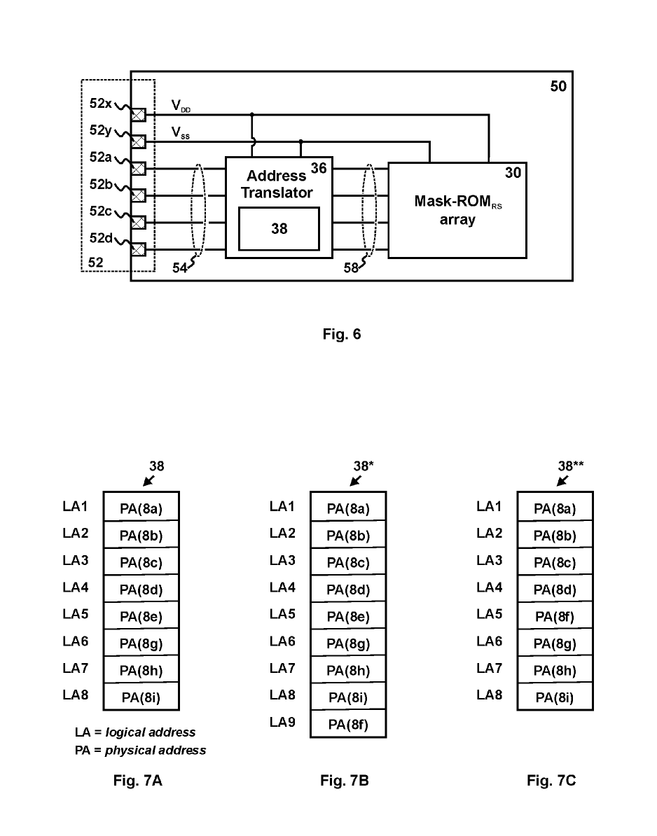

Referring now to FIGS. 6-7C, a preferred 3D-MPROM_{RS} 50 and its address-mapping tables are shown. As illustrated in FIG. 6, the preferred 3D-MPROM_{RS} 50 includes an interface 52 for physically connecting to and electrically communicating with a variety of hosts. The interface 52 includes contacts 52x, 52y, 52a-52d which are coupled to corresponding contacts in a host receptacle. For example, the host provides a voltage supply VDD and a ground voltage V_{SS} to the 3D-MPROM_{RS} 50 through the power contact 52x and the ground contact 52y, respectively; the host further exchanges address/data with the 3D-MPROM_{RS} 50 through signal contacts 52a-52b. Hereinafter, a host is an apparatus that directly uses the 3D-MPROM_{RS} 50, and the address/data used by the host are logical address/data.

The preferred 3D-MPROM_{RS} 50 comprises at least a 3D-MPROM_{RS} array 30 and an address translator 38. The 3D-MPROM_{RS} array 30 is similar to those disclosed in FIGS. 5AA-5BB. The address translator 38 converts logical addresses from the host to physical addresses of the 3D-MPROM_{RS} array 30. Here, the logical addresses are represented on an internal bus 58, while the physical addresses are represented on an external bus 54 (including signals from contacts 52a-52d). The address translator 38 comprises a non-volatile memory (NVM) for storing an address mapping table 38, which maintains links between the logical addresses and the physical addresses. During read, upon receiving the logical address for the memory block to be read, the address translator 36 looks up the address mapping table and fetches the physical address corresponding to the logical address.

The preferred 3D-MPROM_{RS} 50 could comprise a plurality of 3D-MPROM_{RS} arrays. In addition, the 3D-MPROM_{RS} 30 and the address translator 36 could be formed on separate dies or on a single die. When formed on separate dies, the 3D-MPROM_{RS} array die and the address translator die could be vertically stacked or mounted side-by-side. They could form a multi-chip package (MCP) or a multi-chip module (MCM).

FIGS. 7A-7C disclose three exemplary address-mapping tables. Each address-mapping table comprises a plurality of entries. The addresses of these entries are logical addresses, while the data stored in these entries are physical addresses of the content data associated with the logical addresses. For example, the entry at logical address LA1 includes the physical address PA(8a) of at least one memory block storing at least a portion of the content 8a.

The first address-mapping table 38 in FIG. 7A is for an original 3D-MPROM_{RS} 30. Data are written into the original 3D-MPROM_{RS} 30 using the original data-mask 6 of FIG. 4A. The entries at logical addresses LA1-LA8 include the physical addresses for the contents 8a-8e, 8g-8i, respectively.

The second address-mapping table 38* in FIG. 7B is for a first preferred updated 3D-MPROM_{RS} 30*. Data are written into this updated 3D-MPROM_{RS} 30* using the updated data-mask 6* of FIG. 4B. In this updated 3D-MPROM_{RS} 30*, a new content 8f is added to the original content. Accordingly, a new entry is added to the logical address LA9 of the address-mapping table 38*. It contains the physical address PA(8f) for the content 8f. To add new entries, the NVM storing the address-mapping table 38* is preferably a writable memory, which can be programmed at least once. One example of the writable memory is an antifuse-based one-time-programmable memory (OTP), or a flash memory.

The third address-mapping table 38** in FIG. 7C is for a second preferred updated 3D-MPROM_{RS} 30*. Data are written into this updated 3D-MPROM_{RS} 30* using the updated data-mask 6* of FIG. 4B. In this updated 3D-MPROM_{RS} 30*, an upgrade content 8f is included to replace an outdated content 8e. Accordingly, the entry PA(8e) at LA5 is replaced by the physical address PA(8f) for the content 8f. In other words, the address-mapping table 38** does not contain the physical address of the outdated content 8e. To replace entries, the NVM storing the address-mapping table 38** is preferably a re-writable memory, which can be programmed many times. One example of the re-writable memory is a flash memory.

The present invention further discloses a three-dimensional 3D-MPROM with reserved memory level(s) (3D-MPROM_{RL}), which can accommodate at least one large content revision. Versions of the 3D-MPROM_{RL}, including an original 3D-MPROM_{RL} and at least an updated 3D-MPROM_{RL}, collectively form a 3D-MPROM_{RL} family. Within a 3D-MPROM_{RL} family, 3D-MPROM_{RL}'s of different versions are same except for at least a reserved level, which is absent in the original 3D-MPROM_{RL} but present in the updated 3D-MPROM_{RL}. To be more specific, the contents stored in the original 3D-MPROM_{RL} (i.e. the original contents) are also stored in the updated 3D-MPROM_{RL}. While the original 3D-MPROM_{RL} comprises fewer memory levels (i.e. without the reserved memory level) than the updated 3D-MPROM_{RL}, they comprise the same peripheral circuits.

As an example, the original 3D-MPROM_{RL} comprises M (M is a positive integer) memory levels (from the 1^{st} memory level to the M^{th} memory level), whereas the updated 3D-MPROM_{RL} comprises N (N is a positive integer, N>M) memory levels (from the 1^{st} memory level to the M^{th} memory level), where N−M memory levels (from the M+1 th memory level to the M^{th} memory level) are considered as reserved memory levels. Even though it comprises M memory levels, the original 3D-MPROM_{RL} still comprises the peripheral circuits for N(N>M) memory levels. Generally, the first M memory levels of the updated 3D-MPROM_{RL} store the original contents, whereas its next N−M memory levels store the new content. Preferably, the first M memory levels of the updated 3D-MPROM_{RL} are same as the M memory levels of the original 3D-MPROM_{RL}.

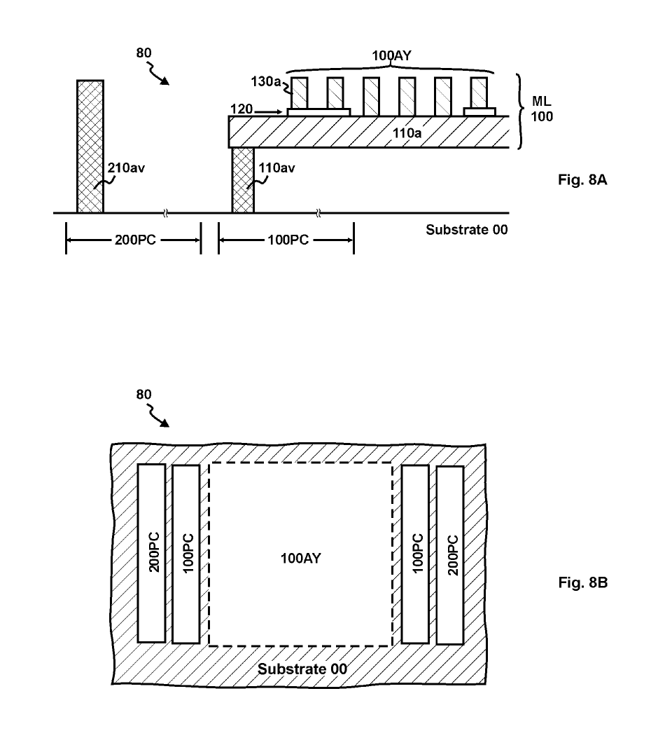

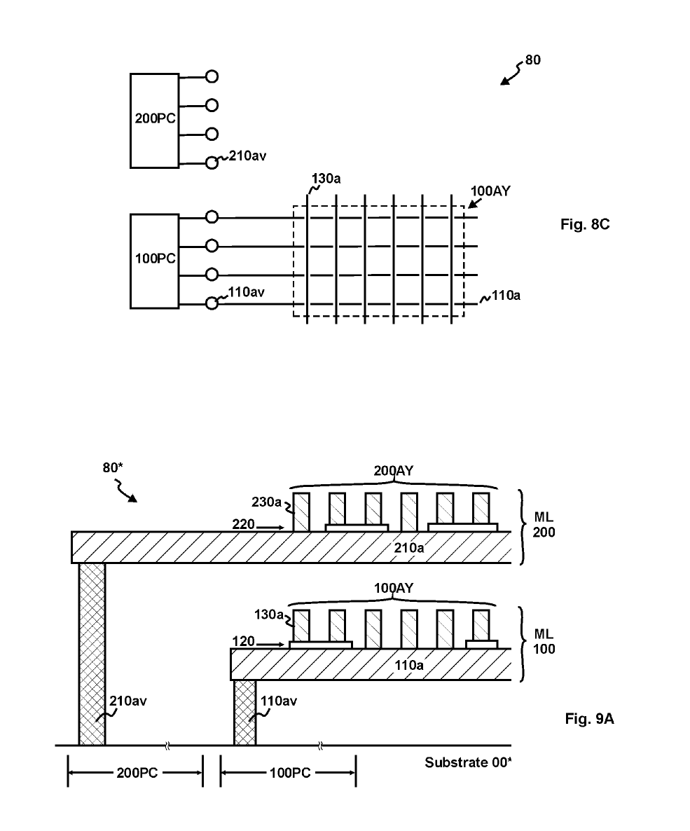

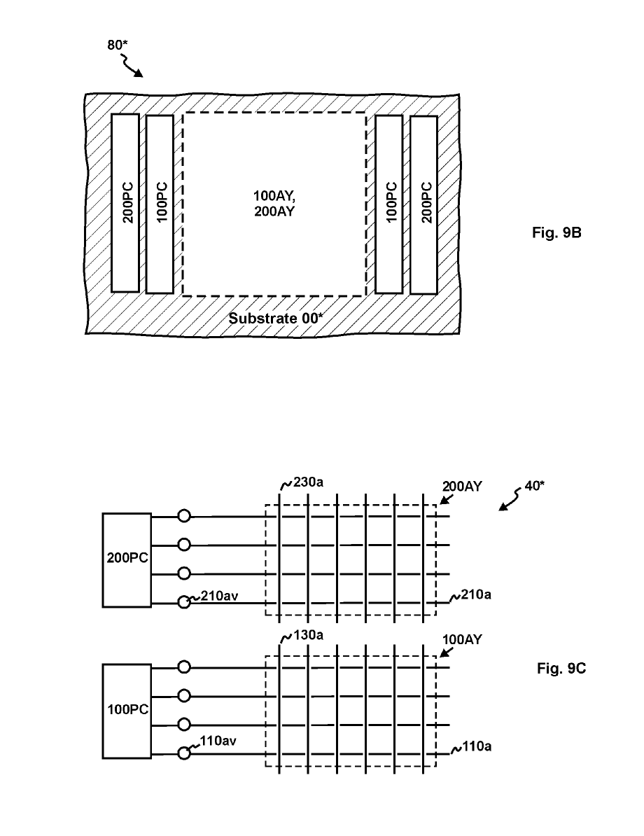

FIGS. 8A-9C disclose a preferred 3D-MPROM_{RL} family. It comprises an original 3D-MPROM_{RL} 80 (FIGS. 8A-8C) and an updated 3D-MPROM_{RL} 80* (FIGS. 9A-9C). The 3D-MPROM_{RL}'s within this 3D-MPROM_{RL} family comprise up to two memory levels, with the first memory level storing the original contents, and the second memory level reserved for the new content. To be more specific, the original 3D-MPROM_{RL} 80 comprises only the first memory level 100, while the updated 3D-MPROM_{RL} 80* comprises both the first memory level 100 and the second memory level 200.

FIGS. 8A-8C disclose various aspects of the original 3D-MPROM_{RL} 80. FIG. 8A is its cross-sectional view. The original 3D-MPROM_{RL} only comprises the first memory level 100, with the second memory level absent. The memory cells at the first memory level 100 form a first memory array 100AY. It stores the original contents, which are defined by the data-layer 120. The peripheral circuit 100PC is coupled with the first memory level 100 through the contact vias (110av . . . ).

FIG. 8B is a top view of the substrate 00 for the original 3D-MPROM_{RL} 80. It comprises the first peripheral circuit 100PC for the first memory level 100, as well as the second peripheral circuit 200PC for the second memory level. Note that, even though the reserved (second) memory level is absent in the original 3D-MPROM_{RL} 80, its peripheral circuit 200PC is still formed on the substrate 00. The projected image of the memory array 100AY on the substrate 00 is also drawn in this figure.

FIG. 8C is a circuit block diagram for the original 3D-MPROM_{RL} 80. The first peripheral circuit 100PC is coupled to the first memory array 100AY and performs read operation for the first memory array 100AY. For reason of simplicity, memory cells and their components (e.g. diodes) are not shown in this figure. Note that the second peripheral circuit 200PC is not coupled to any memory array.

FIGS. 9A-9C disclose various aspects of an updated 3D-MPROM_{RL} 80*. FIG. 9A is its cross-sectional view. The updated 3D-MPROM_{RL} comprises two memory levels 100, 200, with the second memory level 200 formed on top of the first memory level 100. The memory cells at the second memory level 200 form a second memory array 200AY, which stores the new content. The contact via 210av is extended and couples the second memory level 200 with its peripheral circuit 200PC.

FIG. 9B is a top view of the substrate 00* for the updated 3D-MPROM_{RL} 80*. It comprises the first peripheral circuit 100PC and the second peripheral circuit 200PC. Compared with FIG. 8B, the peripheral circuits in the updated 3D-MPROM_{RL} 80* are same as those in the original 3D-MPROM_{RL} 80.

FIG. 9C is a circuit block diagram for the updated 3D-MPROM_{RL} 80*. The first peripheral circuit 100PC performs read operation for the first memory array 100AY; whereas the second peripheral circuit 200PC performs read operation for the second memory array 200AY. For reason of simplicity, memory cells and their components (e.g. diodes) are not shown in this figure.

The 3D-MPROM_{RL} is particularly advantageous for incremental content release. For example, initially the original contents are stored in the first memory level of the original 3D-MPROM_{RL}. After a first time interval, a first new content is released and a first updated 3D-MPROM_{RL} is manufactured. The first new content is stored in the second memory level of the first updated 3D-MPROM_{RL}, with the original contents still stored in its first memory level. After a second time interval, a second new content is released and a second updated 3D-MPROM_{RL} is manufactured. The second new content is stored in the third memory level of the second updated 3D-MPROM_{RL}, with the first new content stored in its second memory level and the original contents stored in its first memory level. In sum, the 3D-MPROM_{RL} can minimize cost for large content revisions.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A three-dimensional mask-programmed read-only memory with reserved level (3D-MPROM_{RL}) family, comprising:
a first 3D-MPROM die comprising a first substrate and M memory levels vertically stacked above said first substrate;
a second 3D-MPROM die comprising a second substrate and N memory levels vertically stacked above said second substrate;
wherein M, N are positive integers and M<N; and, said first and second 3D-MPROM dice are same except for at least a reserved memory level, wherein said reserved memory level is absent in said first 3D-MPROM die but present in said second 3D-MPROM die.

2. The 3D-MPROM_{RL} family according to claim 1, wherein said first and second 3D-MPROM dice comprise same peripheral circuits.

3. The 3D-MPROM_{RL} family according to claim 2, wherein said first 3D-MPROM die comprises the peripheral circuits for said N memory levels.

4. The 3D-MPROM_{RL} family according to claim 2, wherein said second 3D-MPROM die comprises the peripheral circuits for said N memory levels.

5. The 3D-MPROM_{RL} family according to claim 1, wherein N−M memory levels are reserved memory levels.

6. The 3D-MPROM_{RL} family according to claim 1, wherein the contents stored in said first 3D-MPROM die are also stored in said second 3D-MPROM die.

7. The 3D-MPROM_{RL} family according to claim 6, wherein first M memory levels of said second 3D-MPROM die store the same contents as said M memory levels of said first 3D-MPROM die.

8. The 3D-MPROM_{RL} family according to claim 7, wherein first M memory levels of said second 3D-MPROM die are same as said M memory levels of said first 3D-MPROM die.

9. The 3D-MPROM_{RL} family according to claim 1, wherein said M memory levels store the original contents.

10. The 3D-MPROM_{RL} family according to claim 1, wherein said N−M memory levels store the new content.

11. A three-dimensional mask-programmed read-only memory with reserved level (3D-MPROM_{RL}) family, comprising:
a first 3D-MPROM die comprising a first substrate and M memory levels vertically stacked above said first substrate;
a second 3D-MPROM die comprising a second substrate and N memory levels vertically stacked above said second substrate;
wherein M, N are positive integers and M<N; the contents stored in said first 3D-MPROM die are also stored in said second 3D-MPROM die; and, said first and second 3D-MPROM dice comprise same peripheral circuits.

12. The 3D-MPROM_{RL} family according to claim 11, wherein said first 3D-MPROM die comprises the peripheral circuits for said N memory levels.

13. The 3D-MPROM_{RL} family according to claim 11, wherein said second 3D-MPROM die comprises the peripheral circuits for said N memory levels.

14. The 3D-MPROM_{RL} family according to claim 11, wherein N−M memory levels are reserved memory levels.

15. The 3D-MPROM_{RL} family according to claim 14, wherein said first and second 3D-MPROM dice are same except for said reserved memory levels.

16. The 3D-MPROM_{RL} family according to claim 15, wherein said reserved memory levels are absent in said first 3D-MPROM die but present in said second 3D-MPROM die.

17. The 3D-MPROM_{RL} family according to claim 11, wherein first M memory levels of said second 3D-MPROM die store the same contents as said M memory levels of said first 3D-MPROM die.

18. The 3D-MPROM_{RL} family according to claim 17, wherein first M memory levels of said second 3D-MPROM die are same as said M memory levels of said first 3D-MPROM die.

19. The 3D-MPROM_{RL} family according to claim 11, wherein said M memory levels store the original contents.

20. The 3D-MPROM_{RL} family according to claim 11, wherein said N−M memory levels store the new content.
